(19) United States
(12) Patent Application Publication
(10) Pub. No.: US 2025/0369098 A1
(43) Pub. Date: Dec. 4, 2025

(54) DEPOSITION MASK

(71) Applicant: Samsung Display Co., LTD., Yongin-si (KR)

(72) Inventors: Jeong Kuk KIM, Yongin-si (KR); Duck Jung LEE, Yongin-si (KR); Ji Hyun JUNG, Yongin-si (KR); Jun Ho JO, Yongin-si (KR)

(21) Appl. No.: 18/976,120

(22) Filed: Dec. 10, 2024

(30) Foreign Application Priority Data
May 30, 2024 (KR) 10-2024-0070882

(51) Int. Cl. C23C 16/04; H10K 59/12

(52) U.S. Cl. CPC C23C 16/042; H10K 59/12

(57) ABSTRACT

A deposition mask includes: a mask frame having cell openings, and including a rib region defining the cell openings; a membrane including cell regions respectively located above the cell openings and a grid region on the rib region; and first ruler patterns overlapping the rib region in a thickness direction of the mask frame, the first ruler patterns being located at the grid region and spaced from each other by a first interval along a first direction traversing the membrane.

### CROSS-REFERENCE TO RELATED APPLICATION

This application claims priority to and the benefit of Korean Patent Application No. 10-2024-0070882 filed on May 30, 2024, in the Korean Intellectual Property Office, the entire disclosure of which is incorporated by reference herein.

### BACKGROUND

### 1. Field

The present disclosure relates to a deposition mask and an electronic device manufactured by using the same.

### 2. Description of the Related Art

Wearable devices in which a focus is formed at a distance close to user's eyes have been developed in the form of glasses or a helmet. For example, the wearable device may be a head mounted display (HMD) device and/or augmented reality (AR) glasses. The wearable device may provide an augmented reality (hereinafter, referred to as “AR”) screen or a virtual reality (hereinafter, referred to as “VR”) screen to a user.

In the case of wearable devices such as the HMD device or the AR glasses, a display specification of approximately 3000 PPI (pixels per inch) or higher is required to allow users to use them for a long time without symptoms of dizziness. To this end, organic light-emitting diode on silicon (OLEDoS) technology used in high-resolution small-sized organic light-emitting display devices is emerging. The OLEDoS is a technology in which organic light-emitting diodes (OLEDs) are disposed on a semiconductor wafer substrate on which complementary metal oxide semiconductor (CMOS) elements are disposed.

In order to manufacture a display panel with a high resolution of about 3000 PPI or higher, a high-resolution deposition mask is required. For example, the deposition mask may be manufactured by forming a membrane having a plurality of pixel openings on a substrate and partially etching the substrate to form cell openings that expose the pixel openings. However, after manufacturing the above deposition mask, warpage or deformation may occur due to residual stress inside the membrane, difference in thermal expansion rate between the substrate and the membrane, and/or the like.

### SUMMARY

Aspects and features of embodiments of the present disclosure provide an improved deposition mask that allows for the measurement of warpage or deformation, and an electronic device manufactured by using the same.

However, the present disclosure is not limited to those set forth herein. The above and other embodiments of the present disclosure will become more apparent to one of ordinary skill in the art to which the present disclosure pertains by referencing the detailed description of the present disclosure given below.

According to one or more embodiments of the present disclosure, a deposition mask includes: a mask frame having cell openings, and including a rib region defining the cell openings; a membrane including cell regions respectively located above the cell openings and a grid region on the rib region; and first ruler patterns overlapping the rib region in a thickness direction of the mask frame, the first ruler patterns being located at the grid region and spaced from each other by a first interval along a first direction traversing the membrane.

The first direction extends across a central portion of the membrane, and wherein each of the first ruler patterns extends in a second direction intersecting the first direction.

The deposition mask further includes third ruler patterns overlapping the rib region in the thickness direction of the mask frame, and located between the first ruler patterns at a second interval smaller than the first interval along the first direction.

The deposition mask further includes second ruler patterns overlapping the rib region in the thickness direction of the mask frame, the second ruler patterns being located at the grid region and spaced from each other by the first interval along a second direction intersecting the first direction.

The second direction extends across a central portion of the membrane, and wherein each of the second ruler patterns extends in the first direction.

The deposition mask further includes fourth ruler patterns overlapping the rib region in the thickness direction of the mask frame, and located between the second ruler patterns at a second interval smaller than the first interval along the second direction.

The membrane includes an inorganic material, and the first ruler patterns include a metal material.

When the first ruler patterns are in the grid region, the first ruler patterns have a thickness equal to that of the grid region.

When the first ruler patterns are on the grid region, the first ruler patterns have a thickness equal to or less than that of the grid region.

When the mask frame includes a substrate and an inorganic film on the substrate, the cell openings expose the cell regions respectively through the substrate and the inorganic film, and the cell regions have a plurality of pixel openings communicating with the cell openings.

The deposition mask further includes a first reinforcement pattern overlapping the rib region in the thickness direction of the mask frame, extending along the first direction, and located in the grid region.

Each of the first ruler patterns extends from the first reinforcement pattern in a second direction intersecting the first direction.

The first ruler patterns and the first reinforcement pattern are made of a same material.

In one or more embodiments, a deposition mask includes: a mask frame having cell openings, and including a rib region defining the cell openings; a membrane including cell regions respectively located above the cell openings and a grid region on the rib region; first ruler patterns overlapping the rib region in a thickness direction of the mask frame, and located in the grid region at a first interval along a first direction traversing a central portion of the membrane; and second ruler patterns overlapping the rib region in the thickness direction of the mask frame, and located in the grid region at the first interval along a second direction intersecting the first direction while traversing the central portion of the membrane.

Each of the first ruler patterns extends in the second direction, and each of the second ruler patterns extends in the first direction.

The deposition mask further includes: third ruler patterns overlapping the rib region in the thickness direction of the mask frame, and located between the first ruler patterns at a second interval smaller than the first interval along the first direction; and fourth ruler patterns overlapping the rib region in the thickness direction of the mask frame, and located between the second ruler patterns at the second interval along the second direction.

The first ruler patterns and the second ruler patterns have a thickness equal to that of the grid region.

The deposition mask further includes a first reinforcement pattern overlapping the rib region in the thickness direction of the mask frame, extending along the first direction, and located in the grid region; and a second reinforcement pattern overlapping the rib region in the thickness direction of the mask frame, extending along the second direction, and located in the grid region.

Each of the first ruler patterns extends from the first reinforcement pattern in the second direction, and wherein each of the second ruler patterns extends from the second reinforcement pattern in the first direction.

The first ruler patterns and the first reinforcement pattern are made of a same material, and wherein the second ruler patterns and the second reinforcement pattern are made of a same material.

In one or more embodiments, an electronic device includes a display panel including a substrate and a plurality of light-emitting layers formed on the substrate by using a deposition mask. The deposition mask includes a mask frame having cell openings, and comprising a rib region defining the cell openings, a membrane comprising cell regions respectively located above the cell openings and a grid region on the rib region, and first ruler patterns overlapping the rib region in a thickness direction of the mask frame, the first ruler patterns being located at the grid region and spaced from each other by a first interval along a first direction traversing the membrane.

According to the above embodiments, ruler patterns may be disposed in or on a grid region of a membrane, and accordingly, warpage and/or deformation of a deposition mask may be precisely measured using a simple vision camera without a separate measuring device.

Other features and embodiments may be apparent from the following detailed description and the drawings.

### BRIEF DESCRIPTION OF THE DRAWINGS

The above and other aspects and features of the present disclosure will become more apparent by describing in detail example embodiments thereof with reference to the attached drawings, in which:

FIG. 1 is an exploded perspective view illustrating a display device;

FIG. 2 is a block diagram for explaining the display device shown in FIG. 1;

FIG. 3 is an equivalent circuit diagram for explaining an example of a first sub-pixel shown in FIG. 2;

FIG. 4 is a schematic plan view illustrating an example of the display panel shown in FIG. 1;

FIG. 5 is a schematic plan view illustrating an example of the display area shown in FIG. 4;

FIG. 6 is a schematic plan view illustrating another example of the display area shown in FIG. 4;

FIG. 7 is a cross-sectional view illustrating an example of the display panel taken along the line I-I′ of FIG. 5;

FIG. 8 is a schematic perspective view illustrating an example of a head mounted display;

FIG. 9 is a schematic exploded perspective view illustrating the head mounted display shown in FIG. 8;

FIG. 10 is a schematic perspective view illustrating another example of a head mounted display;

FIG. 11 is a schematic plan view illustrating a deposition mask according to one or more embodiments of the present disclosure;

FIG. 12 is a schematic enlarged plan view illustrating cell regions and ruler patterns shown in FIG. 11;

FIG. 13 is a schematic cross-sectional view taken along the line II-II′ shown in FIG. 12;

FIG. 14 is a schematic cross-sectional view taken along the line III-III′ shown in FIG. 12;

FIG. 15 is a cross-sectional view illustrating a deposition mask according to one or more embodiments of the present disclosure;

FIG. 16 is a plan view illustrating a deposition mask according to still another embodiment of the present disclosure; and

FIG. 17 is a schematic enlarged plan view illustrating cell regions and ruler patterns shown in FIG. 16.

### DETAILED DESCRIPTION

Embodiments will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts that are not associated with the description may not be provided in order to describe embodiments of the present disclosure.

It will also be understood that when a layer is referred to as being “on” another layer or substrate, it can be directly on another layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within about ±30% 20% 10% 5% of the stated value.

In the description, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the description, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which the present disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the description.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

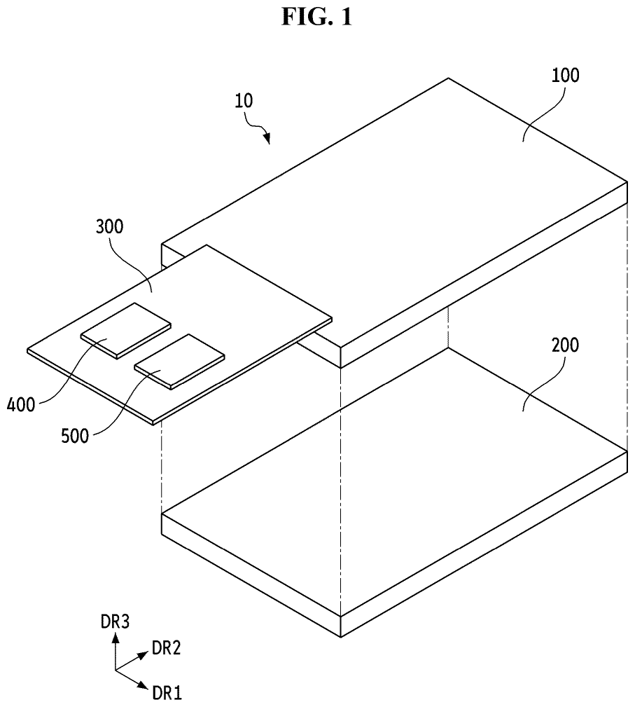

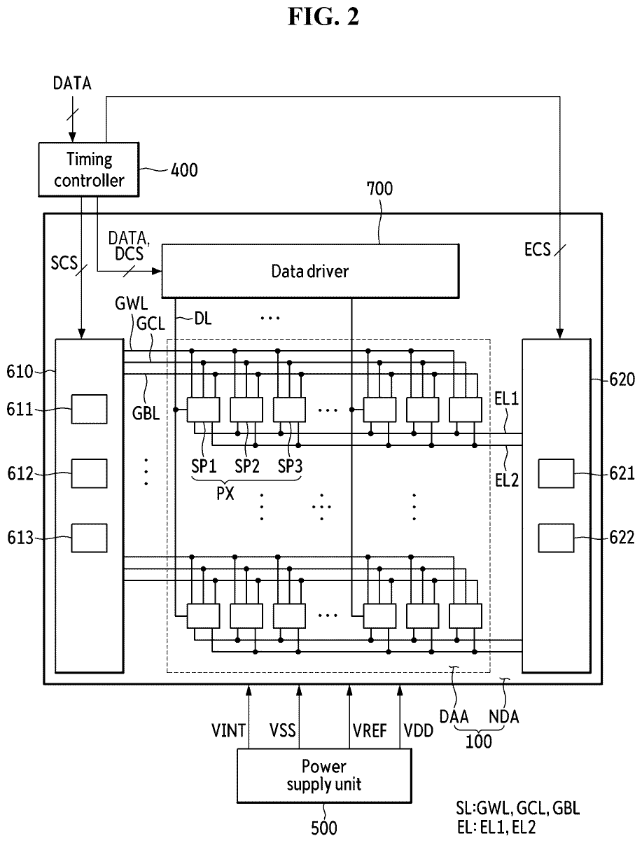

FIG. 1 is an exploded perspective view illustrating a display device. FIG. 2 is a block diagram for explaining the display device shown in FIG. 1.

Referring to FIGS. 1 and 2, a display device 10 may be a device for displaying a moving image and/or a still image. The display device 10 may be applied to portable electronic devices such as a mobile phone, a smartphone, a tablet personal computer (PC), a mobile communication terminal, an electronic organizer, an electronic book, a portable multimedia player (PMP), a navigation system, an ultra-mobile PC (UMPC), and/or the like. For example, the display device 10 may be applied as a display unit of electronic devices such as a television, a laptop, a monitor, a billboard, an Internet-of-Things (IoT) device, and/or the like. Alternatively, the display device 10 may be applied to electronic devices such as a smart watch, a watch phone, a head mounted display (HMD) for implementing virtual reality and augmented reality, and/or the like.

The display device 10 may include a display panel 100, a heat dissipation layer 200, a circuit board 300, a timing control circuit (i.e., timing controller) 400, and a power supply circuit (i.e., power supply unit) 500.

The display panel 100 may have a planar shape similar to a quadrilateral shape. For example, the display panel 100 may have a planar shape similar to a quadrilateral shape, having a short side of a first direction DR1 and a long side of a second direction DR2 intersecting the first direction DR1. In the display panel 100, a corner where a short side in the first direction DR1 and a long side in the second direction DR2 meet may be right-angled or rounded with a suitable curvature (e.g., a predetermined curvature). The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present disclosure is not limited thereto.

The display panel 100 may include a plurality of pixels PX, a plurality of scan lines SL, a plurality of emission control lines EL, a plurality of data lines DL, a scan driver 610, an emission driver 620, and a data driver 700. As shown in FIG. 2, the display panel 100 may be divided into a display area DAA for displaying an image and a non-display area NDA that does not display an image.

The plurality of pixels PX may be disposed in the display area DAA. The plurality of pixels PX may be arranged in a matrix form along the first direction DR1 and the second direction DR2. For example, the plurality of pixels PX may be arranged along rows and columns of a matrix along the first direction DR1 and the second direction DR2. The plurality of scan lines SL and the plurality of emission control lines EL may extend in the first direction DR1, while being arranged along the second direction DR2. The plurality of data lines DL may extend in the second direction DR2, while being arranged along the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines EL1 and a plurality of second emission control lines EL2.

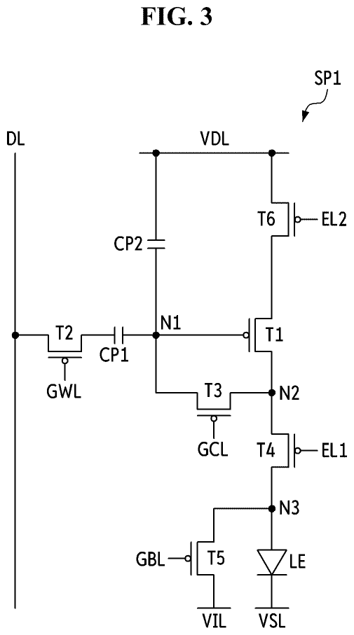

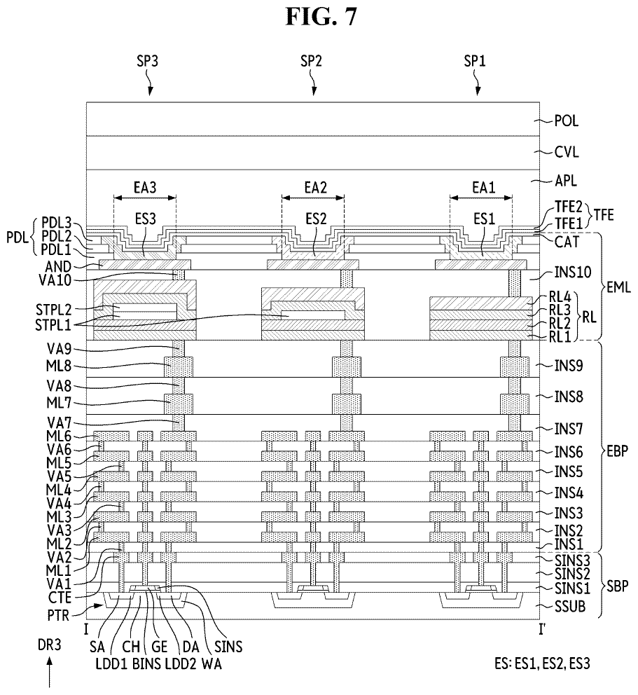

The plurality of pixels PX may include a plurality of sub-pixels SP1, SP2, and SP3. The plurality of sub-pixels SP1, SP2, and SP3 may include a plurality of pixel transistors (see, for example, FIG. 3). The plurality of pixel transistors may be formed by a semiconductor process, and may be disposed on a semiconductor substrate SSUB (see, for example, FIG. 7). For example, the plurality of pixel transistors of the data driver 700 may be formed through a complementary metal oxide semiconductor (CMOS) process, but the present disclosure is not limited thereto.

Each of the plurality of sub-pixels SP1, SP2, and SP3 may be connected to one write scan line GWL from among the plurality of write scan lines GWL, one control scan line GCL from among the plurality of control scan lines GCL, one bias scan line GBL from among the plurality of bias scan lines GBL, one first emission control line EL1 from among the plurality of first emission control lines EL1, one second emission control line EL2 from among the plurality of second emission control lines EL2, and one data line DL from among the plurality of data lines DL. Each of the plurality of sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be disposed in the non-display area NDA.

The scan driver 610 may include a plurality of scan transistors, and the emission driver 620 may include a plurality of light-emitting transistors. The plurality of scan transistors and the plurality of light-emitting transistors may be formed on the semiconductor substrate SSUB (see, for example, FIG. 7) through a semiconductor process. For example, the plurality of scan transistors and the plurality of light-emitting transistors may be formed through a CMOS process, but the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit (i.e., timing controller) 400. The write scan signal output unit 611 may generate write scan signals according to the scan timing control signal SCS of the timing control circuit (i.e., timing controller) 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to bias scan lines GBL.

The emission driver 620 includes a first emission control driver 621 and a second emission control driver 622. Each of the first emission control driver 621 and the second emission control driver 622 may receive an emission timing control signal ECS from the timing control circuit (i.e., timing controller) 400. The first emission control driver 621 may generate first emission control signals according to the emission timing control signal ECS and sequentially output them to the first emission control lines EL1. The second emission control driver 622 may generate second emission control signals according to the emission timing control signal ECS and sequentially output them to the second emission control lines EL2.

The data driver 700 may include a plurality of data transistors, and the plurality of data transistors may be formed through a semiconductor process, and formed on the semiconductor substrate SSUB (see, for example, FIG. 7). For example, the plurality of data transistors may be formed through a CMOS process, but the present disclosure is not limited thereto.

The data driver 700 may receive digital video data DATA and a data timing control signal DCS from the timing control circuit (i.e., timing controller) 400. The data driver 700 converts the digital video data DATA into analog data voltages according to the data timing control signal DCS and outputs the analog data voltages to the data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed on one surface of the display panel 100, for example, on the rear surface thereof. The heat dissipation layer 200 serves to dissipate heat generated from the display panel 100. The heat dissipation layer 200 may include a metal layer having high thermal conductivity, such as graphite, silver (Ag), copper (Cu), and/or aluminum (Al).

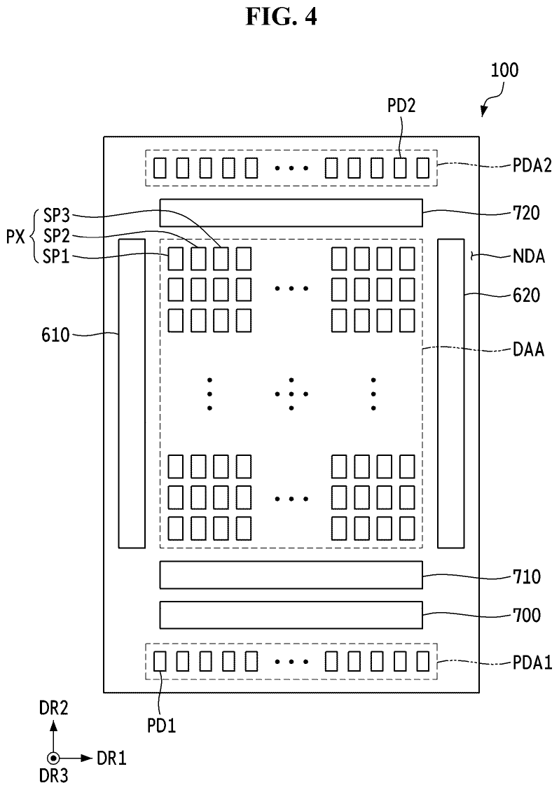

The circuit board 300 may be electrically connected to a plurality of first pads PD1 (see, for example, FIG. 4) of a first pad portion PDA1 (see, for example, FIG. 4) of the display panel 100 by using a conductive adhesive member such as an anisotropic conductive film. The circuit board 300 may be a flexible printed circuit board (FPCB) with a flexible material, or a flexible film. Although the circuit board 300 is illustrated in FIG. 1 as being unfolded, the circuit board 300 may be bent. In this case, one end of the circuit board 300 may be disposed on the rear surface of the display panel 100 and/or the rear surface of the heat dissipation layer 200. The other end of the circuit board 300 may be connected to the plurality of first pads PD1 (see, for example, FIG. 4) of the first pad portion PDA1 (see, for example, FIG. 4) of the display panel 100 by using a conductive adhesive member. One end of the circuit board 300 may be an opposite end of the other end of the circuit board 300.

The timing control circuit (i.e., timing controller) 400 may receive digital video data DATA and timing signals inputted from the outside. The timing control circuit (i.e., timing controller) 400 may generate the scan timing control signal SCS, the emission timing control signal ECS, and the data timing control signal DCS for controlling the display panel 100 in response to the timing signals. The timing control circuit (i.e., timing controller) 400 may output the scan timing control signal SCS to the scan driver 610, and output the emission timing control signal ECS to the emission driver 620. The timing control circuit (i.e., timing controller) 400 may output the digital video data DATA and the data timing control signal DCS to the data driver 700.

The power supply circuit (i.e., power supply unit) 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described later in conjunction with FIG. 3.

Each of the timing control circuit (i.e., timing controller) 400 and the power supply circuit (i.e., power supply unit) 500 may be formed as an integrated circuit (IC) and attached to one surface of the circuit board 300. In this case, the scan timing control signal SCS, the emission timing control signal ECS, digital video data DATA, and the data timing control signal DCS of the timing control circuit (i.e., timing controller) 400 may be supplied to the display panel 100 through the circuit board 300. Further, the first driving voltage VSS, the second driving voltage VDD, and the third driving voltage VINT of the power supply circuit (i.e., power supply unit) 500 may be supplied to the display panel 100 through the circuit board 300.

As another example, each of the timing control circuit (i.e., timing controller) 400 and the power supply circuit (i.e., power supply unit) 500 may be disposed in the non-display area NDA of the display panel 100, similarly to the scan driver 610, the emission driver 620, and the data driver 700. In this case, the timing control circuit (i.e., timing controller) 400 may include a plurality of timing transistors, and each power supply circuit (i.e., power supply unit) 500 may include a plurality of power transistors. The plurality of timing transistors and the plurality of power transistors may be formed through a semiconductor process, and formed on the semiconductor substrate SSUB (see, for example, FIG. 7). For example, the plurality of timing transistors and the plurality of power transistors may be formed through a CMOS process, but the present disclosure is not limited thereto. Each of the timing control circuit 400 and the power supply circuit 500 may be disposed between the data driver 700 and the first pad portion PDA1 (see, for example, FIG. 4).

FIG. 3 is an equivalent circuit diagram for explaining an example of a first sub-pixel shown in FIG. 2.

Referring to FIG. 3, the first sub-pixel SP1 may be connected to the write scan line GWL, the control scan line GCL, the bias scan line GBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. That is, the first driving voltage line VSL may be a low potential voltage line, the second driving voltage line VDL may be a high potential voltage line, and the third driving voltage line VIL may be an initialization voltage line. In this case, the first driving voltage VSS may be lower than the third driving voltage VINT. The second driving voltage VDD may be higher than the third driving voltage VINT.

The first sub-pixel SP1 may include a plurality of transistors T1 to T6, a light-emitting element LE, a first capacitor CP1, and a second capacitor CP2.

The light-emitting element LE emits light in response to a driving current flowing through the channel of the first transistor T1. The emission amount of the light-emitting element LE may be proportional to the driving current. The light-emitting element LE may be disposed between a fourth transistor T4 and the first driving voltage line VSL. The first electrode of the light-emitting element LE may be connected to the drain electrode of the fourth transistor T4, and the second electrode thereof may be connected to the first driving voltage line VSL. The first electrode of the light-emitting element LE may be an anode electrode, and the second electrode of the light-emitting element LE may be a cathode electrode. The light-emitting element LE may be an organic light-emitting diode (OLED) including a first electrode, a second electrode, and an organic light-emitting layer disposed between the first electrode and the second electrode, but the present disclosure is not limited thereto. For example, the light-emitting element LE may be an inorganic light-emitting element including a first electrode, a second electrode, and an inorganic semiconductor disposed between the first electrode and the second electrode, in which case the light-emitting element LE may be a micro light-emitting diode.

The first transistor T1 may be a driving transistor that controls a source-drain current (hereinafter referred to as “driving current”) flowing between the source electrode and the drain electrode thereof according to a voltage applied to the gate electrode thereof. The first transistor T1 may include a gate electrode connected to a first node N1, a source electrode connected to the drain electrode of a sixth transistor T6, and a drain electrode connected to a second node N2.

A second transistor T2 may be disposed between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 may include a gate electrode connected to the write scan line GWL, a source electrode connected to the data line DL, and a drain electrode connected to the one electrode of the first capacitor CP1.

A third transistor T3 may be disposed between the first node N1 and the second node N2. The third transistor T3 is turned on by the control scan signal of the control scan line GCL to connect the first node N1 to the second node N2. For this reason, when the gate electrode and the source electrode of the first transistor T1 are connected, the first transistor T1 may operate like a diode (e.g., the first transistor T1 may be diode-connected). The third transistor T3 may include a gate electrode connected to the control scan line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light-emitting element LE. The fourth transistor T4 may include a gate electrode connected to the first emission control line EL1, a source electrode connected to the second node N2, and a drain electrode connected to the third node N3.

A fifth transistor T5 may be disposed between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE. The fifth transistor T5 may include a gate electrode connected to the bias scan line GBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 may include a gate electrode connected to the second emission control line EL2, a source electrode connected to the second driving voltage line VDL, and a drain electrode connected to the source electrode of the first transistor T1.

The first capacitor CP1 may be disposed between the first node N1 and the drain electrode of the second transistor T2. The first capacitor CP1 may include one electrode connected to the drain electrode of the second transistor T2 and the other electrode connected to the first node N1.

The second capacitor CP2 is formed between the gate electrode of the first transistor T1 (or the first node N1) and the second driving voltage line VDL. The second capacitor CP2 may include one electrode connected to the gate electrode of the first transistor T1 (or the first node N1) and the other electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light-emitting element LE.

Each of the first to sixth transistors T1 to T6 may be a metal-oxide-semiconductor field effect transistor (MOSFET). For example, each of the first to sixth transistors T1 to T6 may be a P-type MOSFET, but the present disclosure is not limited thereto. Each of the first to sixth transistors T1 to T6 may be an N-type MOSFET. Alternatively, some of the first to sixth transistors T1 to T6 may be P-type MOSFETs, and each of the remaining transistors may be an N-type MOSFET.

Although it is illustrated in FIG. 3 that the first sub-pixel SP1 includes six transistors T1 to T6 and two capacitors CP1 and CP2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 will be omitted in the present disclosure.

FIG. 4 is a schematic plan view illustrating an example of the display panel shown in FIG. 1.

Referring to FIG. 4, the display area DAA of the display panel 100 may include the plurality of pixels PX arranged in a matrix form. The non-display area NDA of the display panel 100 may include the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. That is, as shown in FIG. 4, the scan driver 610 may be disposed on the left side of the display area DAA, and the emission driver 620 may be disposed on the right side of the display area DAA. However, the present disclosure is not limited thereto, and the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2. The first pad portion PDA1 may be disposed outside the data driver 700 in the second direction DR2. That is, as shown in FIG. 4, the first pad portion PDA1 may be disposed closer to the edge of the display panel 100 than the data driver 700.

The second pad portion PDA2 may include a plurality of second pads PD2 corresponding to inspection pads that test whether the display panel 100 operates normally. The plurality of second pads PD2 may be connected to a jig or probe pins during an inspection process, or may be connected to a circuit board for inspection. The circuit board for inspection may be a printed circuit board (PCB) made of a rigid material or a flexible printed circuit board (FPCB) made of a flexible material.

The second pad portion PDA2 may be disposed on the fourth side of the display area DAA. For example, the second pad portion PDA2 may be disposed on the other side of the display area DAA in the second direction DR2. The second pad portion PDA2 may be disposed outside the second distribution circuit 720 in the second direction DR2. That is, as shown in FIG. 4, the second pad portion PDA2 may be disposed closer to the edge of the display panel 100 than the second distribution circuit 720.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. That is, as shown in FIG. 4, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. That is, as shown in FIG. 4, the second distribution circuit 720 may be disposed on the upper side of the display area DAA.

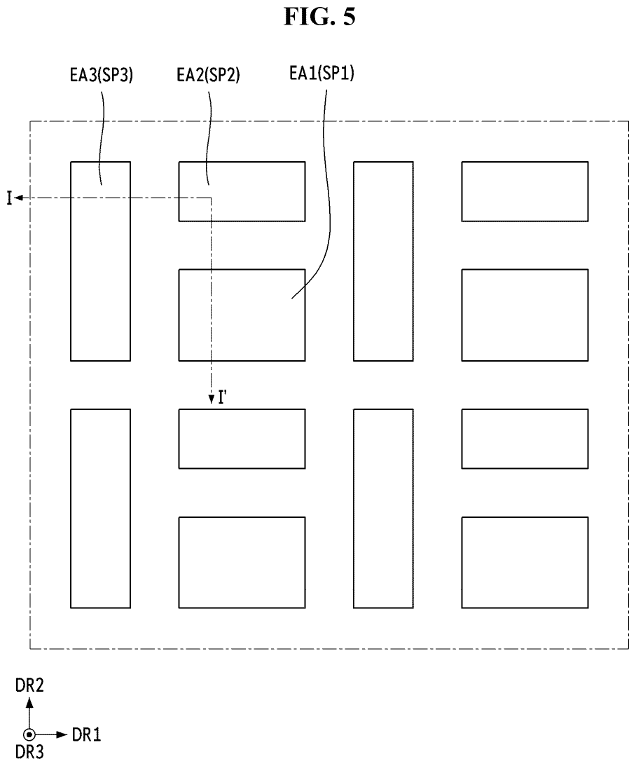

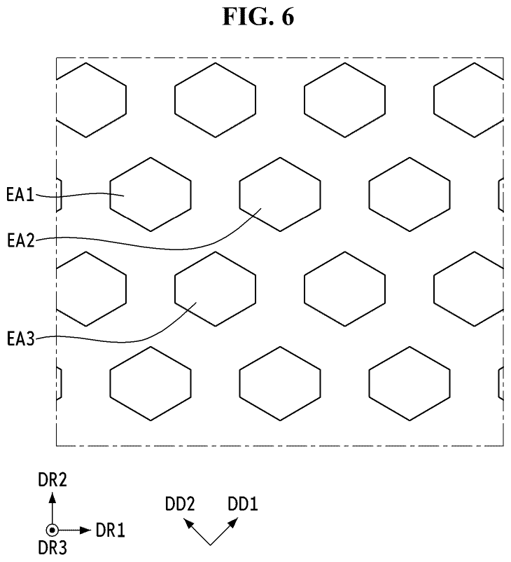

FIG. 5 is a schematic plan view illustrating an example of the display area shown in FIG. 4. FIG. 6 is a schematic plan view illustrating another example of the display area shown in FIG. 4.

Referring to FIG. 5, each of the plurality of pixels PX may include a first sub-pixel SP1, a second sub-pixel SP2, and a third sub-pixel SP3. The first to third sub-pixels SP1, SP2, and SP3 may include emission areas EA1, EA2, and EA3, respectively. For example, the first sub-pixel SP1 may include the first emission area EA1, the second sub-pixel SP2 may include the second emission area EA2, and the third sub-pixel SP3 may include the third emission area EA3.

Each of the first emission area EA1, the second emission area EA2, and the third emission area EA3 may be an area defined by a pixel defining film PDL (see, for example, FIG. 7). For example, each of the first emission area EA1, the second emission area EA2, and the third emission area EA3 may be an area defined by a first pixel defining film PDL1 (see, for example, FIG. 7).

The length of the third emission area EA3 in the first direction DR1 may be less than the length of the first emission area EA1 in the first direction DR1, and the length of the second emission area EA2 in the first direction DR1. The length of the first emission area EA1 in the first direction DR1 and the length of the second emission area EA2 in the first direction DR1 may be substantially the same.

The length of the third emission area EA3 in the second direction DR2 may be greater than the length of the first emission area EA1 in the second direction DR2, and the length of the second emission area EA2 in the second direction DR2. The length of the first emission area EA1 in the second direction DR2 may be greater than the length of the second emission area EA2 in the second direction DR2.

In each of the plurality of pixels PX, the first emission area EA1 and the second emission area EA2 may be adjacent to each other in the second direction DR2. Further, the first emission area EA1 and the third emission area EA3 may be adjacent to each other in the first direction DR1. Further, the second emission area EA2 and the third emission area EA3 may be adjacent to each other in the first direction DR1. The area of the first emission area EA1, the area of the second emission area EA2, and the area of the third emission area EA3 may be different from each other.

The first emission area EA1 may emit light of a first color, the second emission area EA2 may emit light of a second color, and the third emission area EA3 may emit light of a third color. Here, the light of the first color may be light of a red wavelength band, the light of the second color may be light of a green wavelength band, and the light of the third color may be light of a blue wavelength band. For example, the blue wavelength band may be a wavelength band of light whose main peak wavelength is in the range of about 370 nm to about 460 nm, the green wavelength band may be a wavelength band of light whose main peak wavelength is in the range of about 480 nm to about 560 nm, and the red wavelength band may be a wavelength band of light whose main peak wavelength is in the range of about 600 nm to about 750 nm.

As another example, as shown in FIG. 6, the first emission area EA1, the second emission area EA2, and the third emission area EA3 may be disposed in a hexagonal structure having a hexagonal shape in a plan view. In this case, the first emission area EA1 and the second emission area EA2 may be adjacent to each other in the first direction DR1, but the second emission area EA2 and the third emission area EA3 may be adjacent to each other in a first diagonal direction DD1, and the first emission area EA1 and the third emission area EA3 may be adjacent to each other in a second diagonal direction DD2.

Although it is illustrated in FIGS. 5 and 6 that each of the plurality of pixels PX includes the three emission areas EA1, EA2, and EA3, the present disclosure is not limited thereto. That is, each of the plurality of pixels PX may include four emission areas. Further, each of the emission areas EA1, EA2, and EA3 may have a polygonal, circular, elliptical, or atypical shape in a plan view, unlike those shown in FIGS. 5 and 6.

The arrangement of the emission areas EA1, EA2, and EA3 of the plurality of pixels PX is not limited to that illustrated in FIGS. 5 and 6. For example, the emission areas of the plurality of pixels PX may be disposed in a stripe structure in which the emission areas are arranged along the first direction DR1, a PENTILE© structure in which the emission areas are arranged in a diamond shape, and/or the like. PENTILE© is a registered trademark of Samsung Display Co., Ltd., Republic of Korea.

FIG. 7 is a cross-sectional view illustrating an example of the display panel taken along the line I-I′ of FIG. 5.

Referring to FIG. 7, the display panel 100 may include a semiconductor backplane SBP, a light-emitting element backplane EBP, a display element layer EML, an encapsulation layer TFE, an adhesive layer APL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, and/or a silicon-germanium substrate. The semiconductor substrate SSUB may be a substrate doped with a first type impurity. A plurality of well regions WA may be disposed at top surface portions of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA may include a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region DA may be disposed on the other side of the gate electrode GE.

Each of the plurality of well regions WA may further include a first low-concentration impurity region LDD1 disposed between the channel region CH and the source region SA, and a second low-concentration impurity region LDD2 disposed between the channel region CH and the drain region DA. The first low-concentration impurity region LDD1 may be a region having an impurity concentration lower than that of the source region SA. The second low-concentration impurity region LDD2 may be a region having an impurity concentration lower than that of the drain region DA. The distance between the source region SA and the drain region DA may increase due to the presence of the first low-concentration impurity region LDD1 and the second low-concentration impurity region LDD2. Therefore, the length of the channel region CH of each of the pixel transistors PTR may increase, so that punch-through and hot carrier phenomena that might be caused by a short channel may be reduced or prevented.

A first semiconductor insulating film SINS1 may be disposed on the semiconductor substrate SSUB and the gate electrode GE of the pixel transistor PTR. The first semiconductor insulating film SINS1 may be formed of silicon carbonitride (SiCN) and/or a silicon oxide (SiOx)-based inorganic film, but the present disclosure is not limited thereto.

A second semiconductor insulating film SINS2 may be disposed on the first semiconductor insulating film SINS1. The second semiconductor insulating film SINS2 may be formed of a silicon oxide (SiOx)-based inorganic film, but the embodiment of the present specification is not limited thereto.

The plurality of contact terminals CTE may be disposed on the second semiconductor insulating film SINS2. Each of the plurality of contact terminals CTE may be connected to one of the gate electrode GE, the source region SA, or the drain region DA of each of the pixel transistors PTR through contact plugs penetrating the first semiconductor insulating film SINS1 and the second semiconductor insulating film INS2. The plurality of contact terminals CTE may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them.

A third semiconductor insulating film SINS3 may be disposed on side surfaces of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOx)-based inorganic film, but the embodiment of the present specification is not limited thereto.

The semiconductor substrate SSUB may be replaced with a glass substrate or a polymer resin substrate such as polyimide. In this case, thin film transistors may be disposed on the glass substrate and/or the polymer resin substrate. The glass substrate may be a rigid substrate that does not bend, and the polymer resin substrate may be a flexible substrate that can be bent and/or curved.

The light-emitting element backplane EBP may include a plurality of conductive layers ML1 to ML8, a plurality of vias VA1 to VA9, and a plurality of insulating films INS1 to INS9. The plurality of insulating films INS1 to INS9 may be used for electrical insulation between the plurality of conductive layers ML1 to ML8.

The first to eighth conductive layers ML1 to ML8 are connected to the plurality of contact terminals CTE exposed from the semiconductor backplane SBP, and serve to implement the circuit of the first sub-pixel SP1 shown in FIG. 3. For example, the first to sixth transistors T1 to T6 are merely formed in the semiconductor backplane SBP, and the connection of the first to sixth transistors T1 to T6 and the first and second capacitors CP1 and CP2 may be implemented by the first to eighth conductive layers ML1 to ML8. In addition, the connection between the drain region corresponding to the drain electrode of the fourth transistor T4, the source region corresponding to the source electrode of the fifth transistor T5, and a first electrode AND of the light-emitting element LE (see, for example, FIG. 3) may also be implemented by the first to eighth conductive layers ML1 to ML8.

The first insulating film INS1 may be disposed on the semiconductor backplane SBP. Each of the first vias VA1 may penetrate the first insulating film INS1 and be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and may be connected to the first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and may be connected to the second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and may be connected to the third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and may be connected to the fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and may be connected to the fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and may be connected to the sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and may be connected to the seventh conductive layer ML7. Each of the eighth conductive layers ML8 may be disposed on the eighth insulating film INS8 and may be connected to the eighth via VA8.

The first to eighth conductive layers ML1 to ML8 may be made of substantially the same material. The first to eighth conductive layers ML1 to ML8 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The first to eighth vias VA1 to VA8 may be made of substantially the same material. The first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. First to eighth insulating films INS1 to INS8 may be formed of a silicon oxide (SiOx)-based inorganic film, but the embodiment of the present specification is not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be greater than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be greater than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å. The thickness of each of the second conductive layer ML2, the third conductive layer ML3, the fourth conductive layer ML4, the fifth conductive layer ML5, and the sixth conductive layer ML6 may be approximately 1440 Å. The thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be greater than the thickness of each of the first conductive layer ML1, the second conductive layer ML2, the third conductive layer ML3, the fourth conductive layer ML4, the fifth conductive layer ML5, and the sixth conductive layer ML6. The thickness of the seventh conductive layer ML7 and the thickness of the eighth conductive layer ML8 may be greater than the thickness of the seventh via VA7 and the thickness of the eighth via VA8, respectively. The thickness of each of the seventh via VA7 and the eighth via VA8 may be greater than the thickness of each of the first via VA1, the second via VA2, the third via VA3, the fourth via VA4, the fifth via VA5, and the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9,000 Å. The thickness of each of the seventh via VA7 and the eighth via VA8 may be approximately 6,000 Å.

A ninth insulating film INS9 may be disposed on the eighth insulating film INS8 and the eighth conductive layer ML8. The ninth insulating film INS9 may be formed of a silicon oxide (SiOx)-based inorganic film, but the embodiment of the present specification is not limited thereto.

Each of the ninth vias VA9 may penetrate the ninth insulating film INS9 and may be connected to the eighth conductive layer ML8. The ninth vias VA9 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. The thickness of the ninth via VA9 may be approximately 16,500 Å.

The display element layer EML may be disposed on the light-emitting element backplane EBP. The display element layer EML may include a reflective electrode layer RL, a tenth insulating film INS10, a tenth via VA10, light-emitting elements LE, and a pixel defining film PDL. Each of the light-emitting elements LE may include a first electrode AND, a light-emitting stack ES, and a second electrode CAT.

The reflective electrode layer RL may be disposed on the ninth insulating film INS9. The reflective electrode layer RL may include at least one reflective electrode RL1, RL2, RL3, and RL4, a first step layer STPL1, and a second step layer STPL2. For example, the reflective electrode layer RL may include first to fourth reflective electrodes RL1, RL2, RL3, and RL4 as shown in FIG. 7.

Each of the first reflective electrodes RL1 may be disposed on the ninth insulating film INS9, and may be connected to the ninth via VA9. The first reflective electrodes RL1 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the first reflective electrodes RL1 may include titanium nitride (TiN).

Each of the second reflective electrodes RL2 may be disposed on the first reflective electrode RL1. The second reflective electrodes RL2 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the second reflective electrodes RL2 may include aluminum (Al).

The first step layer STPL1 may be disposed on the second reflective electrode RL2 in the second sub-pixel SP2 and the third sub-pixel SP3. The first step layer STPL1 may not be disposed on the second reflective electrode RL2 in the first sub-pixel SP1.

The second step layer STPL2 may be disposed on the first step layer STPL1 in the third sub-pixel SP3. The second step layer STPL2 may not be disposed on the second reflective electrode RL2 in the third sub-pixel SP3. In addition, the second step layer STPL2 may not be disposed on the first step layer STPL1 in the second sub-pixel SP2.

The thickness of the first step layer STPL1 may be set in consideration of the wavelength of the light of the second color and a distance from the light-emitting stack ES of the second sub-pixel SP2 to the fourth reflective electrode RL4 to reflect (e.g., advantageously reflect) the light of the second color emitted from the light-emitting stack ES. The thickness of the second step layer STPL2 may be set in consideration of the wavelength of the light of the third color and a distance from the light-emitting stack ES of the third sub-pixel SP3 to the fourth reflective electrode RL4 to reflect (e.g., advantageously reflect) the light of the third color emitted from the light-emitting stack ES.

The first step layer STPL1 and the second step layer STPL2 may be formed of silicon carbonitride (SiCN) and/or a silicon oxide (SiOx)-based inorganic film, but the present disclosure is not limited thereto.

In the first sub-pixel SP1, the third reflective electrode RL3 may be disposed on the second reflective electrode RL2. In the second sub-pixel SP2, the third reflective electrode RL3 may be disposed on the first step layer STPL1 and the second reflective electrode RL2. In the third sub-pixel SP3, the third reflective electrode RL3 may be disposed on the second step layer STPL2 and the second reflective electrode RL2. The third reflective electrodes RL3 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the third reflective electrodes RL3 may include titanium nitride (TiN).

At least one of the first reflective electrode RL1, the second reflective electrode RL2, and the third reflective electrode RL3 may be omitted.

Each of the fourth reflective electrodes RL4 may be disposed on the third reflective electrode RL3. The fourth reflective electrodes RL4 may be a layer that reflects light from the light-emitting stack ES. The fourth reflective electrodes RL4 may include metal having high reflectivity to reflect (e.g., advantageously reflect) the light. In addition, because the fourth reflective electrode RL4 is an electrode that substantially reflects light from the light-emitting elements LE, the thickness of the fourth reflective electrode RL4 may be greater than the thickness of each of the first reflective electrode RL1, the second reflective electrode RL2, and the third reflective electrode RL3. The fourth reflective electrodes RL4 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the fourth reflective electrodes RL4 may include aluminum (Al) and/or titanium (Ti). However, in one or more embodiments, the thickness of the fourth reflective electrode RL4 may be substantially the same as the thickness of each of the first reflective electrode RL1, the second reflective electrode RL2, and the third reflective electrode RL3.

The tenth insulating film INS10 may be disposed on the ninth insulating film INS9 and the fourth reflective electrodes RL4. The tenth insulating film INS10 may be an optical auxiliary layer through which light reflected by the reflective electrode layer RL passes, from among light emitted from the light-emitting elements LE. The tenth insulating film INS10 may be formed of a silicon oxide (SiOx)-based inorganic film, but the present disclosure is not limited thereto.

Each of the tenth vias VA10 may penetrate the tenth insulating film INS10 and may be connected to the reflective electrode layer RL. The tenth vias VA10 may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them.

The thicknesses of the tenth vias VA10 may be different in the first sub-pixel SP1, the second sub-pixel SP2, and the third sub-pixel SP3 in order to adjust a resonance distance of light emitted from the light-emitting elements LE in at least one of the first sub-pixel SP1, the second sub-pixel SP2, or the third sub-pixel SP3. For example, the thickness of the tenth via VA10 in the third sub-pixel SP3 may be less than the thickness of the tenth via VA10 in each of the first sub-pixel SP1 and the second sub-pixel SP2. Further, the thickness of the tenth via VA10 in the second sub-pixel SP2 may be smaller than the thickness of the tenth via VA10 in the first sub-pixel SP1. That is, the distance between the light-emitting stack ES and the reflective electrode layer RL may be different in the first sub-pixel SP1, the second sub-pixel SP2, and the third sub-pixel SP3.

In summary, in order to adjust the distance between the light-emitting stack ES and the reflective electrode layer RL according to the main wavelength of light emitted from the first sub-pixel SP1, the second sub-pixel SP2, and the third sub-pixel SP3, the presence or absence of the first and second step layers STPL1 and STPL2 and the thickness of each of the first and second step layers STPL1 and STPL2 in the first sub-pixel SP1, the second sub-pixel SP2, and the third sub-pixel SP3 may be set.

The first electrode AND of each of the light-emitting elements LE may be disposed on the tenth insulating film INS10 and connected to the tenth via VA10. The first electrode AND of each of the light-emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light-emitting elements LE may be formed of copper (Cu), aluminum (Al), tungsten (W), molybdenum (Mo), chromium (Cr), gold (Au), titanium (Ti), nickel (Ni), and/or neodymium (Nd), and/or an alloy including one or more of them. For example, the first electrode AND of each of the light-emitting elements LE may be titanium nitride (TiN).

The pixel defining film PDL may be disposed on the tenth insulating film INS10 and a part of the first electrode AND of each of the light-emitting elements LE. The pixel defining film PDL may cover the edge of the first electrode AND of each of the light-emitting elements LE. The pixel defining film PDL may serve to partition the first emission areas EA1, the second emission areas EA2, and the third emission areas EA3. That is, the pixel defining film PDL may have openings that partially expose the first electrode AND of each of the light-emitting elements LE.

The first emission area EA1 may be defined as an area in which the first electrode AND, the light-emitting stack ES, and the second electrode CAT are sequentially stacked in the first sub-pixel SP1 to emit light. The second emission area EA2 may be defined as an area in which the first electrode AND, the light-emitting stack ES, and the second electrode CAT are sequentially stacked in the second sub-pixel SP2 to emit light. The third emission area EA3 may be defined as an area in which the first electrode AND, the light-emitting stack ES, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the tenth insulating film INS10 and the first electrode AND of each of the light-emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOx)-based inorganic film, but the present disclosure is not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film increases, so that a first encapsulation inorganic film TFE1 may be cut off due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, in order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. For example, the widths of the openings of the first pixel defining film PDL1 may be less than the widths of the openings of the second pixel defining film PDL2, and the widths of the openings of the second pixel defining film PDL2 may be less than the widths of the openings of the third pixel defining film PDL3.

The light-emitting stack ES may include a first light-emitting stack ES1 disposed in the first emission area EA1, a second light-emitting stack ES2 disposed in the second emission area EA2, and a third light-emitting stack ES3 disposed in the third emission area EA3. In one or more embodiments, the first light-emitting stack ES1 may include a hole injecting layer, a hole transporting layer, a first light-emitting layer, an electron transporting layer, and an electron injecting layer, the second light-emitting stack ES2 may include the hole injecting layer, the hole transporting layer, a second light-emitting layer, the electron transporting layer, and the electron injecting layer, and the third light-emitting stack ES3 may include the hole injecting layer, the hole transporting layer, a third light-emitting layer, the electron transporting layer, and the electron injecting layer.

For example, the hole injecting layer may be disposed on the first electrodes AND exposed by the openings of the pixel defining film PDL, the inner surfaces of the openings of the pixel defining film PDL, and the top surface of the pixel defining film PDL. The hole transporting layer may be disposed on the hole injecting layer.

The first to third light-emitting layers may be respectively disposed in the openings of the pixel defining film PDL on the hole transporting layer. The first light-emitting layer may be disposed in the opening of the pixel defining film PDL in the first emission area EA1, and may emit light of a first color, for example, red light. The second light-emitting layer may be disposed in the opening of the pixel defining film PDL in the second emission area EA2, and may emit light of a second color, for example, green light. The third light-emitting layer may be disposed in the opening of the pixel defining film PDL in the third emission area EA3, and may emit light of a third color, for example, blue light.

The electron transporting layer may be disposed on the first to third light-emitting layers and the hole transporting layer, and the electron injecting layer may be disposed on the electron transporting layer.

For another example, in one or more embodiments, a plurality of trenches may be disposed between the first to third emission areas EA1, EA2, and EA3. The trenches may have a ring shape respectively surrounding the first to third emission areas EA1, EA2, and EA3, and may be formed to penetrate the pixel defining film PDL. The hole injecting layer and the hole transporting layer formed on the first electrodes AND of the first to third emission areas EA1, EA2, and EA3 may be disconnected from each other by the trenches.

For another example, the first to third light-emitting stacks ES1, ES2, and ES3 may be respectively disposed in the openings of the pixel defining film PDL, and may not be disposed on the pixel defining film PDL. In this case, the first to third light-emitting stacks ES1, ES2, and ES3 may be disconnected from each other by the pixel defining film PDL.

The second electrode CAT may be disposed on the first to third light-emitting stacks ES1, ES2, and ES3 and the pixel defining film PDL. The second electrode CAT may be formed of a transparent conductive material (TCO) such as ITO and/or IZO that can transmit light or a semi-transmissive conductive material such as magnesium (Mg), silver (Ag), and/or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to reduce and/or prevent oxygen or moisture from permeating into the display element layer EML. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNx), silicon oxynitride (SiON), and/or silicon oxide (SiOx) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOx) and/or aluminum oxide (AlOx), but the present disclosure is not limited thereto. The second encapsulation inorganic film TFE2 may be formed by an atomic layer deposition (ALD) process. The thickness of the second encapsulation inorganic film TFE2 may be less than the thickness of the first encapsulation inorganic film TFE1.

The adhesive layer APL may be a layer for increasing the interfacial adhesion between the encapsulation layer TFE and the cover layer CVL. The adhesive layer APL may be an organic film such as acrylic resin, epoxy resin, phenolic resin, polyamide resin, or polyimide resin.

The cover layer CVL may be disposed on the adhesive layer APL. The cover layer CVL may be a glass substrate and/or a polymer resin. When the cover layer CVL is a glass substrate, it may be attached onto the adhesive layer APL, and may serve as an encapsulation substrate. When the cover layer CVL is a polymer resin, it may be directly applied onto the adhesive layer APL.

The polarizing plate POL may be disposed on the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the present disclosure is not limited thereto.

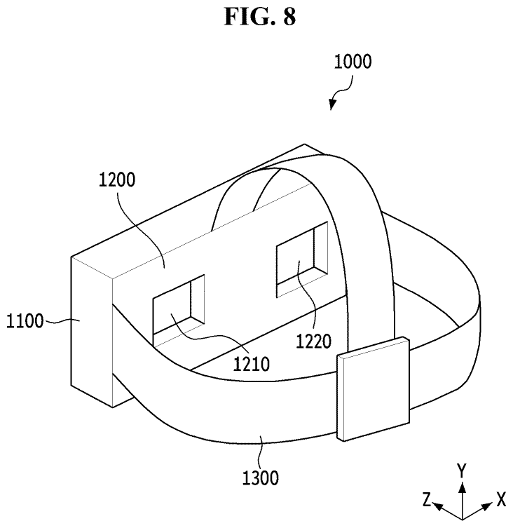

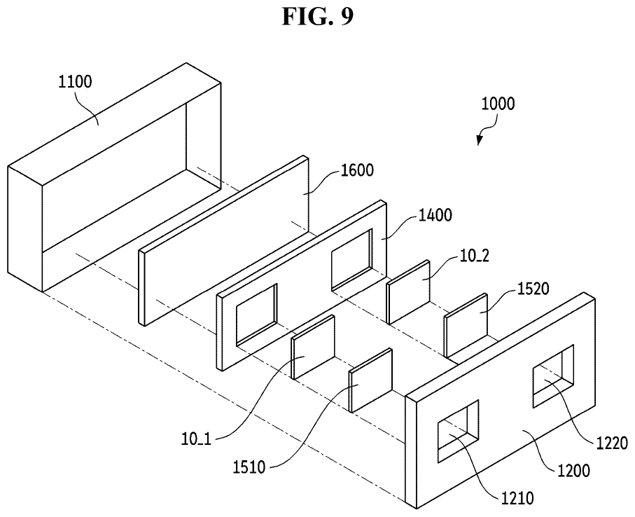

FIG. 8 is a schematic perspective view illustrating a head mounted display. FIG. 9 is a schematic exploded perspective view illustrating an example of the head mounted display shown in FIG. 8.

Referring to FIGS. 8 and 9, a head mounted display 1000 according to one or more embodiments may include a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 may provide an image to the user's left eye, and the second display device 10_2 provides an image to the user's right eye. Because each of the first display device 10_1 and the second display device 10_2 is substantially the same as the display device 10 described in conjunction with FIGS. 1 and 2, description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first and second display devices 10_1 and 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through a connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 102, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIGS. 8 and 9 illustrate that the first eyepiece 1210 and the second eyepiece 1220 are disposed separately, but the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

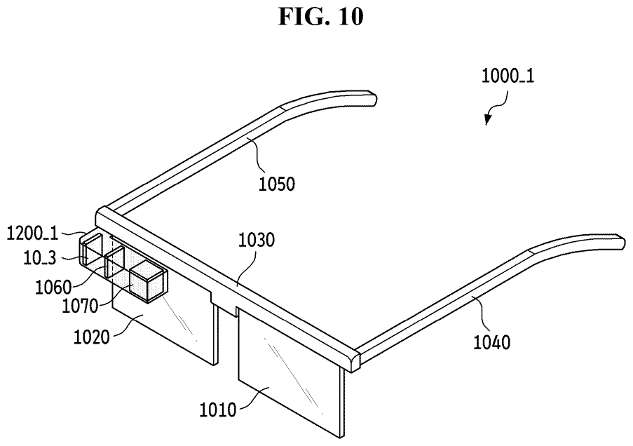

The head mounted band 1300 serves to secure the display device housing 1100 to the user's head such that the first eyepiece 1210 and the second eyepiece 1220 of the housing cover 1200 remain located on the user's left and right eyes, respectively. When the display device housing 1100 is implemented to be lightweight and compact, the head mounted display 1000 may be provided in the form of glasses as shown in FIG. 10.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a schematic perspective view illustrating another example of a head mounted display.

Referring to FIG. 10, a head mounted display 1000_1 may be an eyeglasses-type display device in which a display device housing 1200_1 is implemented in a lightweight and compact manner. The head mounted display 1000_1 may include a display device 10_3, a left eye lens 1010, a right eye lens 1020, a support frame 1030, temples 1040 and 1050, an optical member 1060, an optical path conversion member 1070, and the display device housing 1200_1.

The display device housing 1200_1 may include the display device 103, the optical member 1060, and the optical path conversion member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 10 illustrates that the display device housing 1200_1 is disposed at the right end of the support frame 1030, but the present disclosure is not limited thereto. For example, the display device housing 1200_1 may be disposed at the left end of the support frame 1030, and in this case, the image of the display device 10_3 may be provided to the user's left eye. As another example, the display device housing 1200_1 may be disposed at both the left and right ends of the support frame 1030, and in this case, the user may view the image displayed on the display device 10_3 through both the left and right eyes.

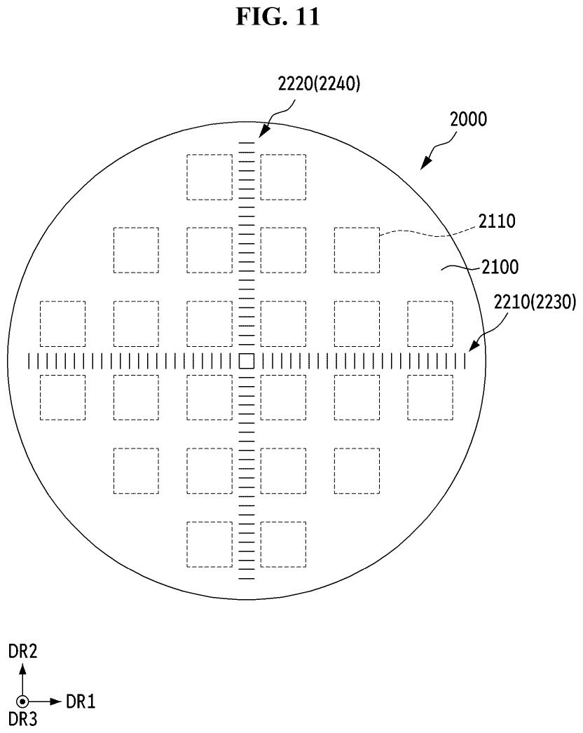

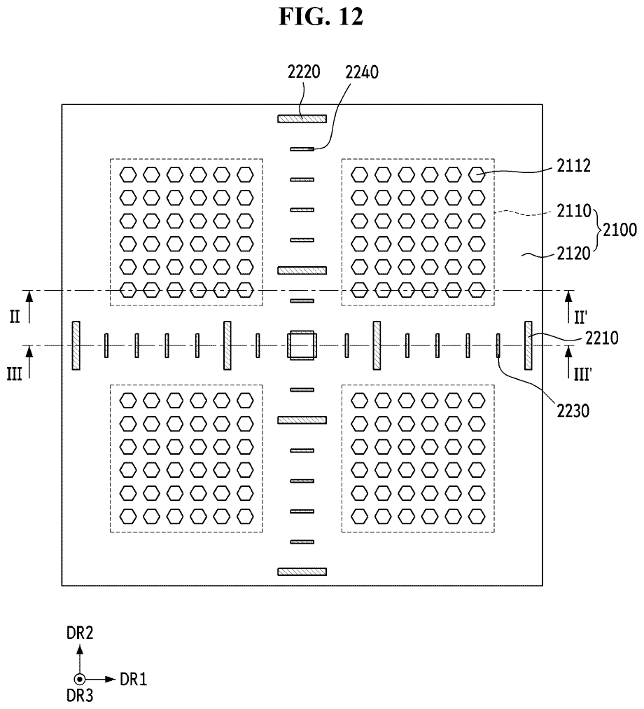

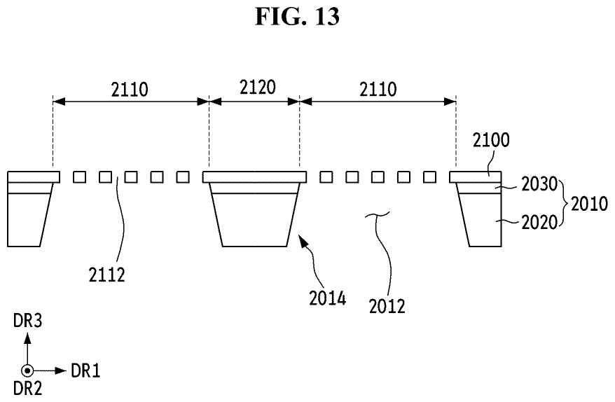

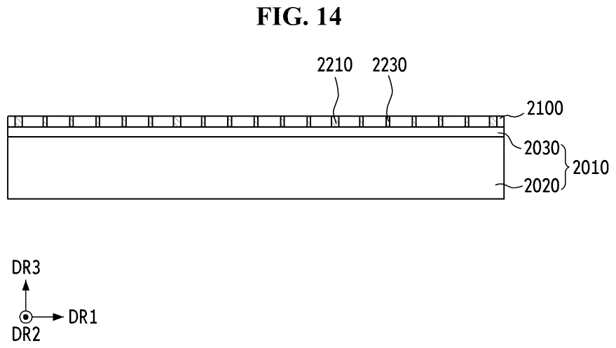

FIG. 11 is a schematic plan view illustrating a deposition mask according to one or more embodiments of the present disclosure. FIG. 12 is a schematic enlarged plan view illustrating cell regions and ruler patterns shown in FIG. 11. FIG. 13 is a schematic cross-sectional view taken along the line II-II′ shown in FIG. 12. FIG. 14 is a schematic cross-sectional view taken along the line III-III′ shown in FIG. 12.

Referring to FIGS. 11-14, a deposition mask 2000 according to one or more embodiments of the present disclosure may be used as a shadow mask in a deposition process for forming light-emitting layers of a light-emitting stack ES on a display substrate (or a backplane substrate) in order to manufacture a display panel 100 (see FIG. 1). For example, as illustrated in FIG. 7, the semiconductor backplane SBP and the light emitting element backplane EBP may be disposed on the display substrate, and the reflective electrodes RL and the insulating film INS10 may be disposed on the light emitting element backplane EBP. Electrode patterns, for example, the anode electrodes AND may be disposed on the insulating film INS10, and the anode electrodes AND may be electrically connected to the reflective electrodes RL through the vias VA10. As an example, the deposition mask 2000 may be used to form first light-emitting layers for emitting first light having a blue wavelength band on electrode patterns of the first emission areas EA1. As another example, the deposition mask 2000 may be used to form second light-emitting layers for emitting second light having a green wavelength band on electrode patterns of the second emission areas EA2. As still another example, the deposition mask 2000 may be used to form third light-emitting layers for emitting third light having a blue wavelength band on electrode patterns of the third emission areas EA3.

The deposition mask 2000 may include a mask frame 2010 and a membrane 2100 disposed on the mask frame 2010. The mask frame 2010 may have a plurality of cell openings 2012 and may include a rib region 2014 defining the cell openings 2012. The membrane 2100 may include a plurality of cell regions 2110 respectively disposed above the cell openings 2012 and a grid region 2120 disposed on the rib region 2014 of the mask frame 2010.

As shown in FIG. 11, the cell regions 2110 may be arranged in a matrix form along the first direction DR1 and the second direction DR2 intersecting the first direction DR1. For example, the cell regions 2110 may be arranged in a matrix form along a first horizontal direction and a second horizontal direction perpendicular to the first horizontal direction. However, because the number and arrangement directions of the cell regions 2110 may be variously changed, the scope of the present disclosure is not limited thereby.

The mask frame 2010 may have the plurality of cell openings 2012 respectively corresponding to the cell regions 2110 of the membrane 2100. For example, the cell openings 2012 may be formed to penetrate the mask frame 2010 through a dry and/or wet etching process, so that the cell regions 2110 of the membrane 2100 may be exposed respectively through the cell openings 2012.

In addition, the mask frame 2010 may include a substrate 2020 and an inorganic film 2030 disposed on the substrate 2020. In this case, the cell openings 2012 may be formed to penetrate the substrate 2020 and the inorganic film 2030. For example, a silicon substrate may be used as the substrate 2020, and a silicon oxide film may be used as the inorganic film 2030. For example, a silicon oxide film formed through a thermal oxidation process or a chemical vapor deposition process may be used as the inorganic film 2030. However, the inorganic film 2030 may be made of a material different from the above material, and accordingly, the scope of the present disclosure is not limited by the silicon oxide film.

The membrane 2100 may be made of a material different from that of the inorganic film 2030. For example, a silicon nitride film formed through a chemical vapor deposition process may be used as the membrane 2100. In this case, the inorganic film 2030 may function as an adhesive film between the substrate 2020 and the membrane 2100. However, the membrane 2100 may be made of a material different from the above material, and accordingly, the scope of the present disclosure is not limited by the silicon nitride film.

In addition, each of the cell regions 2110 of the membrane 2100 may have a plurality of pixel openings 2112. The pixel openings 2112 may function as paths for providing a light-emitting material in a deposition process for forming the light-emitting layers of the light-emitting stack ES. For example, as shown in FIG. 12, the pixel openings 2112 may be arranged in a matrix form along the first and second directions DR1 and DR2, and may be formed to penetrate the cell regions 2110 of the membrane 2100 through an anisotropic etching process after forming the membrane 2100 on the inorganic film 2030. In this case, the inorganic film 2030 may function as an etch stop film during the anisotropic etching process. The cell openings 2012 may be formed to expose the cell regions 2110 after the pixel openings 2112 are formed, thereby allowing the pixel openings 2112 to communicate with the cell openings 2012.

In one or more embodiments, the deposition mask 2000 may be warped or deformed by residual stress generated during the manufacturing process as described above, and in this case, the deposition mask 2000 may not be sufficiently brought into close contact with a backplane substrate during the deposition process for forming the light-emitting layers. In particular, the warpage or deformation of the deposition mask 2000 may mainly occur during the etching process for forming the cell openings 2012, and accordingly, it is necessary to measure the warpage and/or deformation of the deposition mask 2000 after forming the cell openings 2012.

According to one or more embodiments of the present disclosure, the deposition mask 2000 may include ruler patterns 2210, 2220, 2230, and 2240 for measuring warpage and/or deformation. For example, the deposition mask 2000 may include a plurality of first ruler patterns 2210 arranged in a direction traversing the membrane 2100. Specifically, the first ruler patterns 2210 may overlap the rib region 2014 of the mask frame 2010 in a thickness direction of the mask frame 2010 (e.g., the third direction DR3), and may be disposed in the grid region 2120 of the membrane 2100. In particular, the first ruler patterns 2210 may be arranged at a suitable first interval (e.g., a predetermined first interval) along the first direction DR1 traversing the membrane 2100. In this case, the first direction DR1 may extend across the central portion of the membrane 2100, and each of the first ruler patterns 2210 may extend in the second direction DR2 intersecting the first direction DR1. For example, the second direction DR2 may be perpendicular to the first direction DR1, and the thickness direction may be the third direction DR3 perpendicular to the first and second directions DR1 and DR2.

The deposition mask 2000 may include second ruler patterns 2220 disposed in the grid region 2120 at the first interval along the second direction DR2 intersecting the first direction DR1. In particular, the second ruler patterns 2220 may overlap the rib region 2014 of the mask frame 2010 in the thickness direction of the mask frame 2010. In this case, the second direction DR2 may extend across the central portion of the membrane 2100, and each of the second ruler patterns 2220 may extend in the first direction DR1. In addition, each of the second ruler patterns 2220 may have the same length and width as those of the first ruler patterns 2210.

In one or more embodiments, when a cell region (hereinafter, referred to as “central cell region”) is disposed on the central portion of the mask frame 2010, the first ruler patterns may be disposed in the grid region 2120 in a fourth direction parallel to the first direction DR1 to be adjacent to the central cell region, and the second ruler patterns may be disposed in the grid region 2120 in a fifth direction parallel to the second direction DR2 to be adjacent to the central cell region.

The deposition mask 2000 may include third ruler patterns 2230 disposed between the first ruler patterns 2210, as shown in FIG. 12. For example, the third ruler patterns 2230 may overlap the rib region 2014 of the mask frame 2010 in the thickness direction of the mask frame 2010 (e.g., the third direction DR3), and may be disposed in the grid region 2120 of the membrane 2100 along the first direction DR1. In this case, the third ruler patterns 2230 may be arranged at a second interval smaller than the first interval. In addition, each of the third ruler patterns 2230 may have a smaller length and width than those of the first ruler patterns 2210, and may extend in the second direction DR2.

The deposition mask 2000 may include fourth ruler patterns 2240 disposed between the second ruler patterns 2220, as shown in FIG. 12. For example, the fourth ruler patterns 2240 may overlap the rib region 2014 of the mask frame 2010 in the thickness direction of the mask frame 2010 (e.g., the third direction DR3), and may be disposed in the grid region 2120 of the membrane 2100 along the second direction DR2. In this case, the fourth ruler patterns 2240 may be arranged at the second interval. In addition, each of the fourth ruler patterns 2240 may have a smaller length and width than those of the second ruler patterns 2220, and may extend in the first direction DR1. For example, each of the fourth ruler patterns 2240 may have the same length and width as those of the third ruler patterns 2230.

The first, second, third, and fourth ruler patterns 2210, 2220, 2230, and 2240 may include a metal material. For example, the first, second, third, and fourth ruler patterns 2210, 2220, 2230, and 2240 may be made of a metal material such as tungsten (W), molybdenum (Mo), chromium (Cr), titanium (Ti), iron (Fe), nickel (Ni), tungsten nitride (WN), titanium nitride (TiN), invar alloy, and/or the like, and may be formed through a chemical vapor deposition process, an atomic layer deposition process, a physical vapor deposition process, an electroforming process, and/or the like.

For example, after a second inorganic film for forming the membrane 2100 is formed on the inorganic film 2030, a photoresist pattern may be formed on the second inorganic film to expose portions where the first, second, third, and fourth ruler patterns 2210, 2220, 2230, and 2240 are to be formed, and an anisotropic etching process may be performed using the photoresist pattern as an etch mask to form a plurality of recesses that penetrate the second inorganic film and expose the inorganic film 2030. In this case, the inorganic film 2030 may function as an etch stop film in the anisotropic etching process. Subsequently, a metal film made of the above metal material may be formed on the second inorganic film such that the recesses are buried, and then a planarization process such as a chemical mechanical polishing process may be performed to form the first, second, third, and fourth ruler patterns 2210, 2220, 2230, and 2240 in the recesses. In this case, the planarization process may be performed until the second inorganic film is exposed such that the first, second, third, and fourth ruler patterns 2210, 2220, 2230, and 2240 have the same thickness as the second inorganic film. As a result, the first, second, third, and fourth ruler patterns 2210, 2220, 2230, and 2240 may be exposed through the top surface of the second inorganic film, i.e., the membrane 2100, so as to be observable from the outside.

After the first, second, third, and fourth ruler patterns 2210, 2220, 2230, and 2240 are formed as described above, a photoresist pattern may be formed on the second inorganic film to expose portions where the pixel openings 2112 are to be formed, and an anisotropic etching process may be performed using the photoresist pattern as an etch mask to form the pixel openings 2112 that penetrate the second inorganic film and expose the inorganic film 2030. As a result, the membrane 2100 having the pixel openings 2112 may be formed from the second inorganic film.

Meanwhile, the cell openings 2012 may be formed by partially removing the mask frame 2010. For example, the cell openings 2012 may be formed by forming a photoresist pattern or a hard mask pattern on the back surface of the substrate 2020 to expose portions where the cell openings 2012 are to be formed, and then performing a dry and/or wet etching process using the photoresist pattern or the hard mask pattern as an etch mask. In this case, the substrate 2020 and the inorganic film 2030 may be partially removed by the dry and/or wet etching process, thereby forming the cell openings 2012 that respectively expose the cell regions 2110 of the membrane 2100.

According to the present embodiment, because the first, second, third, and fourth ruler patterns 2210, 2220, 2230, and 2240 may be exposed through the top surface of the membrane 2100, the first, second, third, and fourth ruler patterns 2210, 2220, 2230, and 2240 may be identified from the top of the deposition mask 2000. Therefore, the warpage or deformation of the deposition mask 2000 may be precisely measured using a simple vision camera, without the need for a separate measuring device equipped with a laser displacement sensor.

For example, after manufacturing the deposition mask 2000, a vision camera may be disposed above the deposition mask 2000, the first, second, third, and fourth ruler patterns 2210, 2220, 2230, and 2240 may be detected using the vision camera, and the intervals between the first, second, second, third, and fourth ruler patterns 2210, 2220, 2230, and 2240 may be measured. When warpage or deformation occurs during the manufacturing process of the deposition mask 2000, the intervals between the first, second, third, and fourth ruler patterns 2210, 2220, 2230, and 2240 may be changed, and the measured intervals between the first, second, third, and fourth ruler patterns 2210, 2220, 2230, and 2240 may be compared with suitable intervals (e.g., predetermined intervals) so as to determine the degree of warpage and/or deformation of the deposition mask 2000.

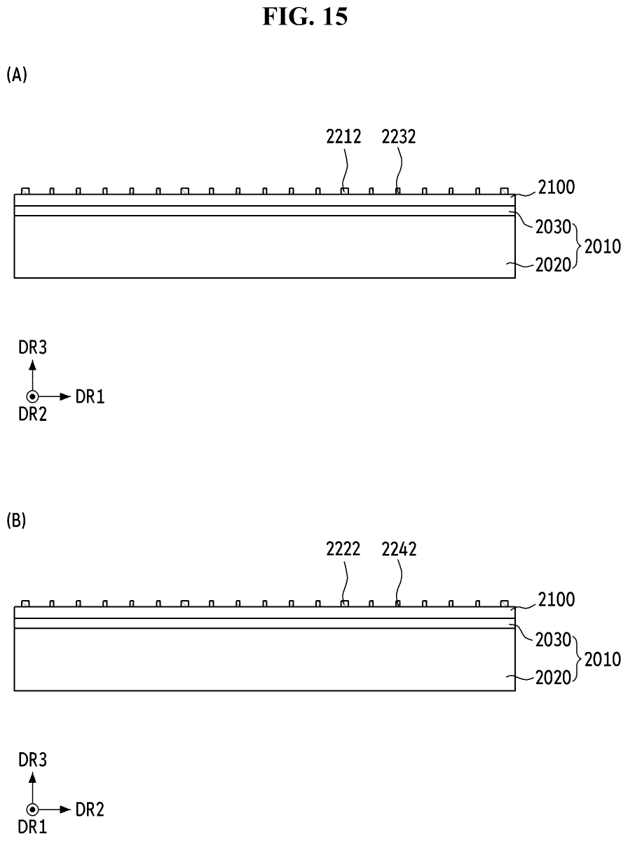

FIG. 15 is a cross-sectional view illustrating a deposition mask according to one or more embodiments of the present disclosure.

Referring to FIG. 15, the deposition mask 2000 according to one or more embodiments of the present disclosure may include the mask frame 2010, the membrane 2100 disposed on the mask frame 2010, and first ruler patterns 2212 disposed on the membrane 2100. In addition, the deposition mask 2000 may include second ruler patterns 2222, third ruler patterns 2232, and fourth ruler patterns 2242 disposed on the membrane 2100. The mask frame 2010 may have the plurality of cell openings 2012 and may include the rib region 2014 defining the cell openings 2012. The membrane 2100 may include the cell regions 2110 respectively disposed above the cell openings 2012 and the grid region 2120 disposed on the rib region 2014 of the mask frame 2010.

The first ruler patterns 2212 may overlap the rib region 2014 in the thickness direction of the mask frame 2010 (e.g., the third direction DR3) and may be disposed on the grid region 2120 of the membrane 2100 at a suitable first interval (e.g., a predetermined first interval) along the first direction DR1 traversing the membrane 2100. The second ruler patterns 2222 may overlap the rib region 2014 in the thickness direction of the mask frame 2010 (e.g., the third direction DR3) and may be disposed on the grid region 2120 of the membrane 2100 at the first interval along the second direction DR2 intersecting the first direction DR1.

The third ruler patterns 2232 may overlap the rib region 2014 in the thickness direction of the mask frame 2010 (e.g., the third direction DR3) and may be disposed between the first ruler patterns 2212 on the grid region 2120 of the membrane 2100 at a second interval smaller than the first interval along the first direction DR1. The fourth ruler patterns 2242 may overlap the rib region 2014 in the thickness direction of the mask frame 2010 (e.g., the third direction DR3) and may be disposed between the second ruler patterns 2222 on the grid region 2120 of the membrane 2100 at the second interval along the second direction DR2.

According to the present embodiment, when the first ruler patterns 2212 are disposed on the grid region 2120 of the membrane 2100, the first ruler patterns 2212 may be formed to have a thickness equal to or less than the thickness of the grid region 2120, and the third ruler patterns 2232 may be formed to have the same thickness as the first ruler patterns 2212. In addition, the second and fourth ruler patterns 2222 and 2242 may be formed to have the same thickness as the first ruler patterns 2212.

The first, second, third, and fourth ruler patterns 2212, 2222, 2232, and 2242 may include a metal material. For example, the first, second, third, and fourth ruler patterns 2212, 2222, 2232, and 2242 may be made of a metal material such as tungsten (W), molybdenum (Mo), chromium (Cr), titanium (Ti), iron (Fe), nickel (Ni), tungsten nitride (WN), titanium nitride (TiN), invar alloy, and/or the like, and may be formed through a chemical vapor deposition process, an atomic layer deposition process, a physical vapor deposition process, an electroforming process, and/or the like. Specifically, after a second inorganic film for forming the membrane 2100 is formed on the inorganic film 2030, a metal film including the metal material may be formed on the second inorganic film, and then patterned to form the first, second, third, and fourth ruler patterns 2212, 2222, 2232, and 2242.

In the present embodiment, the mask frame 2010 and the membrane 2100 are substantially the same as those described above with reference to FIGS. 11-14, and thus detailed descriptions thereof will be omitted.

According to the present embodiment, the first, second, third, and fourth ruler patterns 2212, 2222, 2232, and 2242 may be disposed on the membrane 2100, and accordingly, the first, second, third, and fourth ruler patterns 2212, 2222, 2232, and 2242 may be identified from the top of the deposition mask 2000. Therefore, the warpage or deformation of the deposition mask 2000 may be precisely measured using a simple vision camera, without the need for a separate measuring device.

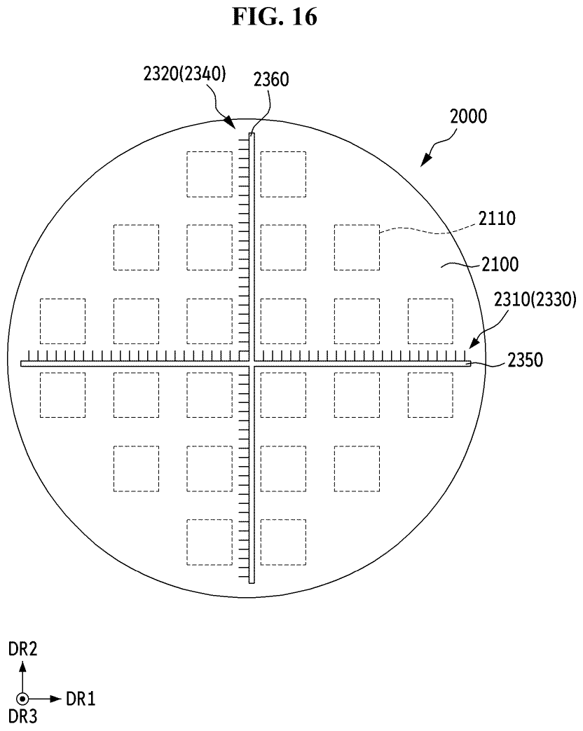

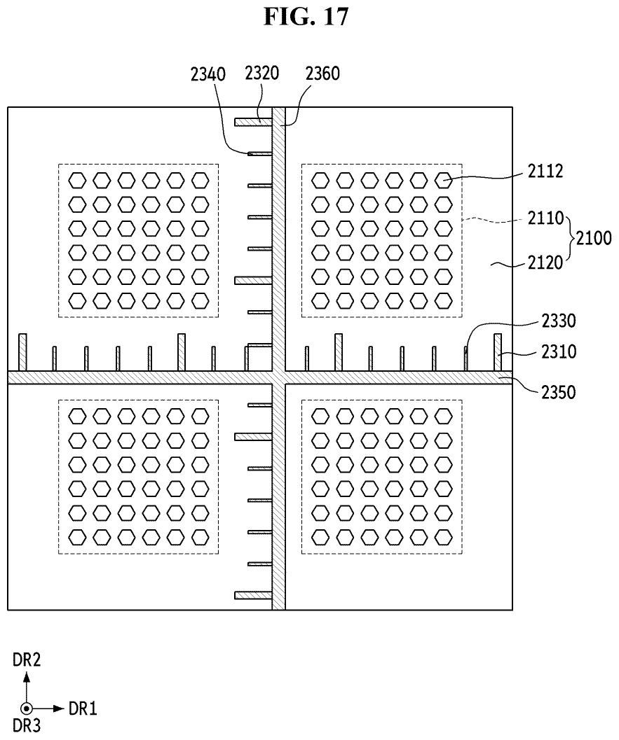

FIG. 16 is a plan view illustrating a deposition mask according to still another embodiment of the present disclosure. FIG. 17 is a schematic enlarged plan view illustrating cell regions and ruler patterns shown in FIG. 16.

Referring to FIGS. 16 and 17, the deposition mask 2000 according to still another embodiment of the present disclosure may include the mask frame 2010, the membrane 2100 disposed on the mask frame 2010, and first, second, third, and fourth ruler patterns 2310, 2320, 2330, and 2340 disposed in the membrane 2100. In addition, the deposition mask 2000 may include first and second reinforcement patterns 2350 and 2360 disposed in the membrane.

The mask frame 2010 may include the plurality of cell openings 2012 and the rib region 2014 defining the cell openings 2012. The membrane 2100 may include the cell regions 2110 respectively disposed above the cell openings 2012 and the grid region 2120 disposed on the rib region 2014 of the mask frame 2010. In the present embodiment, the mask frame 2010 and the membrane 2100 are substantially the same as those described above with reference to FIGS. 11-14, and thus detailed descriptions thereof will be omitted.

According to the present embodiment, the deposition mask 2000 may include the ruler patterns 2310, 2320, 2330, and 2340 for measuring warpage or deformation. For example, the deposition mask 2000 may include the plurality of first ruler patterns 2310 arranged in a direction traversing the membrane 2100. Specifically, the first ruler patterns 2310 may overlap the rib region 2014 of the mask frame 2010 in a thickness direction of the mask frame 2010, and may be disposed in the grid region 2120 of the membrane 2100. In particular, the first ruler patterns 2310 may be arranged at a suitable first interval (e.g., a predetermined first interval) along the first direction DR1 traversing the membrane 2100. In this case, the first direction DR1 may extend across the central portion of the membrane 2100, and each of the first ruler patterns 2310 may extend in the second direction DR2 intersecting the first direction DR1. For example, the second direction DR2 may be perpendicular to the first direction DR1, and the thickness direction may be the third direction DR3 perpendicular to the first and second directions DR1 and DR2.

The deposition mask 2000 may include the second ruler patterns 2320 disposed in the grid region 2120 of the membrane 2100 at the first interval along the second direction DR2 intersecting the first direction DR1. In particular, the second ruler patterns 2320 may overlap the rib region 2014 of the mask frame 2010 in the thickness direction of the mask frame 2010. In this case, the second direction DR2 may extend across the central portion of the membrane 2100, and each of the second ruler patterns 2320 may extend in the first direction DR1. In addition, each of the second ruler patterns 2320 may have the same length and width as those of the first ruler patterns 2310.

In one or more embodiments, when a cell region (hereinafter, referred to as “central cell region”) is disposed on the central portion of the mask frame 2010, the first ruler patterns may be disposed in the grid region 2120 of the membrane 2100 in a fourth direction parallel to the first direction DR1 to be adjacent to the central cell region, and the second ruler patterns may be disposed in the grid region 2120 of the membrane 2100 in a fifth direction parallel to the second direction DR2 to be adjacent to the central cell region.

The deposition mask 2000 may include the third ruler patterns 2330 disposed between the first ruler patterns 2310, as shown in FIG. 17. For example, the third ruler patterns 2330 may overlap the rib region 2014 of the mask frame 2010 in the thickness direction of the mask frame 2010 (e.g., the third direction DR3), and may be disposed in the grid region 2120 of the membrane 2100 along the first direction DR1. In this case, the third ruler patterns 2330 may be disposed at a second interval smaller than the first interval. In addition, each of the third ruler patterns 2330 may have a smaller length and width than those of the first ruler patterns 2310, and may extend in the second direction DR2.

The deposition mask 2000 may include the fourth ruler patterns 2340 disposed between the second ruler patterns 2320, as shown in FIG. 17. For example, the fourth ruler patterns 2340 may overlap the rib region 2014 of the mask frame 2010 in the thickness direction of the mask frame 2010, and may be disposed in the grid region 2120 of the membrane 2100 along the second direction DR2. In this case, the fourth ruler patterns 2340 may be arranged at the second interval. In addition, each of the fourth ruler patterns 2340 may have a smaller length and width than those of the second ruler patterns 2320, and may extend in the first direction DR1. For example, each of the fourth ruler patterns 2340 may have the same length and width as those of the third ruler patterns 2330.

The first, second, third, and fourth ruler patterns 2310, 2320, 2330, and 2340 may include a metal material. For example, the first, second, third, and fourth ruler patterns 2310, 2320, 2330, and 2340 may be made of a metal material such as tungsten (W), molybdenum (Mo), chromium (Cr), titanium (Ti), iron (Fe), nickel (Ni), tungsten nitride (WN), titanium nitride (TiN), invar alloy, and/or the like, and may be formed through a chemical vapor deposition process, an atomic layer deposition process, a physical vapor deposition process, an electroforming process, and/or the like.

According to the present embodiment, the first and second reinforcement patterns 2350 and 2360 may be used to reduce the warpage and/or deformation of the deposition mask 2000. For example, as shown in FIGS. 16 and 17, the first reinforcement pattern 2350 may overlap the rib region 2014 of the mask frame 2010 in the thickness direction of the mask frame 2010 (e.g., the third direction DR3) and may be disposed in the grid region 2120 of the membrane 2100. In particular, the first reinforcement pattern 2350 may extend along the first direction DR1, and each of the first and third ruler patterns 2310 and 2330 may extend from the first reinforcement pattern 2350 in the second direction DR2.

Specifically, the second reinforcement patterns 2360 may overlap the rib region 2014 of the mask frame 2010 in a thickness direction of the mask frame 2010 (e.g., the third direction DR3), and may be disposed in the grid region 2120 of the membrane 2100. In particular, the second reinforcement pattern 2360 may extend along the second direction DR2, and each of the second and fourth ruler patterns 2320 and 2340 may extend from the second reinforcement pattern 2360 in the first direction DR1.

The first and second reinforcement regions 2350 and 2360 may include a metal material. For example, the first and second reinforcement regions 2350 and 2360 may be made of a metal material such as tungsten (W), molybdenum (Mo), chromium (Cr), titanium (Ti), iron (Fe), nickel (Ni), tungsten nitride (WN), titanium nitride (TiN), invar alloy, and/or the like and may be formed through a chemical vapor deposition process, an atomic layer deposition process, a physical vapor deposition process, an electroforming process, and/or the like.

The first, second, third, and fourth ruler patterns 2310, 2320, 2330, and 2340 and the first and second reinforcement patterns 2350 and 2360 may be concurrently (e.g., simultaneously) formed using the same material. For example, after a second inorganic film for forming the membrane 2100 is formed on the inorganic film 2030, a photoresist pattern may be formed on the second inorganic film to expose portions where the first, second, third, and fourth ruler patterns 2310, 2320, 2330, and 2340 and the first and second reinforcement patterns 2350 and 2360 are to be formed, and an anisotropic etching process may be performed using the photoresist pattern as an etch mask to form a plurality of recesses that penetrate the second inorganic film and expose the inorganic film 2030. In this case, the inorganic film 2030 may function as an etch stop film in the anisotropic etching process. Subsequently, a metal film made of the above metal material may be formed on the second inorganic film such that the recesses are buried, and then a planarization process such as a chemical mechanical polishing process may be performed to form the first, second, third, and fourth ruler patterns 2310, 2320, 2330, and 2340 and the first and second reinforcement patterns 2350 and 2360 in the recesses. In this case, the planarization process may be performed until the second inorganic film, i.e., the membrane 2100, is exposed such that the first, second, third, and fourth ruler patterns 2310, 2320, 2330, and 2340 and the first and second reinforcement patterns 2350 and 2360 have the same thickness as the second inorganic film. As a result, the first, second, third, and fourth ruler patterns 2310, 2320, 2330, and 2340 and the first and second reinforcement patterns 2350 and 2360 may have the same thickness as the membrane 2100 and may be exposed through the top surface of the membrane 2100 so as to be observable from the outside.

According to the present embodiment, the first, second, third, and fourth ruler patterns 2310, 2320, 2330, and 2340 may be detected using a simple vision camera without the need for a separate measuring device, thereby precisely measuring the warpage or deformation of the deposition mask 2000. In addition, according to the present embodiment, the stiffness of the deposition mask 2000 may be increased by the first and second reinforcement patterns 2350 and 2360, and accordingly, the warpage or deformation of the deposition mask 2000 may be reduced.

The above description is an example of technical features of the present disclosure, and those skilled in the art to which the present disclosure pertains will be able to make various modifications and variations. Therefore, the embodiments of the present disclosure described above may be implemented separately or in combination with each other.

In concluding the detailed description, those skilled in the art will appreciate that many variations and modifications may be made to the embodiments without substantially departing from the principles, and spirit and scope of the present disclosure. Therefore, the embodiments are used in a generic and descriptive sense only and not for purposes of limitation.

What is claimed is:

1. A deposition mask comprising:
a mask frame having cell openings, and comprising a rib region defining the cell openings;
a membrane comprising cell regions respectively located above the cell openings and a grid region on the rib region; and
first ruler patterns overlapping the rib region in a thickness direction of the mask frame, the first ruler patterns being located at the grid region and spaced from each other by a first interval along a first direction traversing the membrane.

2. The deposition mask of claim 1, wherein the first direction extends across a central portion of the membrane, and
wherein each of the first ruler patterns extends in a second direction intersecting the first direction.

3. The deposition mask of claim 1, further comprising third ruler patterns overlapping the rib region in the thickness direction of the mask frame, and located between the first ruler patterns at a second interval smaller than the first interval along the first direction.

4. The deposition mask of claim 1, further comprising second ruler patterns overlapping the rib region in the thickness direction of the mask frame, the second ruler patterns being located at the grid region and spaced from each other by the first interval along a second direction intersecting the first direction.

5. The deposition mask of claim 4, wherein the second direction extends across a central portion of the membrane, and
wherein each of the second ruler patterns extends in the first direction.

6. The deposition mask of claim 4, further comprising fourth ruler patterns overlapping the rib region in the thickness direction of the mask frame, and located between the second ruler patterns at a second interval smaller than the first interval along the second direction.

7. The deposition mask of claim 1, wherein the membrane comprises an inorganic material, and the first ruler patterns comprise a metal material.

8. The deposition mask of claim 1, wherein when the first ruler patterns are in the grid region, the first ruler patterns have a thickness equal to that of the grid region.

9. The deposition mask of claim 1, wherein when the first ruler patterns are on the grid region, the first ruler patterns have a thickness equal to or less than that of the grid region.

10. The deposition mask of claim 1, wherein when the mask frame comprises a substrate and an inorganic film on the substrate,
the cell openings expose the cell regions respectively through the substrate and the inorganic film, and
the cell regions have a plurality of pixel openings communicating with the cell openings.

11. The deposition mask of claim 1, further comprising a first reinforcement pattern overlapping the rib region in the thickness direction of the mask frame, extending along the first direction, and located in the grid region.

12. The deposition mask of claim 11, wherein each of the first ruler patterns extends from the first reinforcement pattern in a second direction intersecting the first direction.

13. The deposition mask of claim 11, wherein the first ruler patterns and the first reinforcement pattern are made of a same material.

14. A deposition mask comprising:
a mask frame having cell openings, and comprising a rib region defining the cell openings;
a membrane comprising cell regions respectively located above the cell openings and a grid region on the rib region;
first ruler patterns overlapping the rib region in a thickness direction of the mask frame, and located in the grid region at a first interval along a first direction traversing a central portion of the membrane; and
second ruler patterns overlapping the rib region in the thickness direction of the mask frame, and located in the grid region at the first interval along a second direction intersecting the first direction while traversing the central portion of the membrane.

15. The deposition mask of claim 14, wherein each of the first ruler patterns extends in the second direction, and each of the second ruler patterns extends in the first direction.

16. The deposition mask of claim 14, further comprising:
third ruler patterns overlapping the rib region in the thickness direction of the mask frame, and located between the first ruler patterns at a second interval smaller than the first interval along the first direction; and
fourth ruler patterns overlapping the rib region in the thickness direction of the mask frame, and located between the second ruler patterns at the second interval along the second direction.

17. The deposition mask of claim 14, wherein the first ruler patterns and the second ruler patterns have a thickness equal to that of the grid region.

18. The deposition mask of claim 14, further comprising a first reinforcement pattern overlapping the rib region in the thickness direction of the mask frame, extending along the first direction, and located in the grid region; and
a second reinforcement pattern overlapping the rib region in the thickness direction of the mask frame, extending along the second direction, and located in the grid region.

19. The deposition mask of claim 18, wherein each of the first ruler patterns extends from the first reinforcement pattern in the second direction, and
wherein each of the second ruler patterns extends from the second reinforcement pattern in the first direction.

20. The deposition mask of claim 18, wherein the first ruler patterns and the first reinforcement pattern are made of a same material, and
wherein the second ruler patterns and the second reinforcement pattern are made of a same material.

21. An electronic device comprising a display panel comprising a substrate and a plurality of light-emitting layers formed on the substrate by using a deposition mask comprising:
a mask frame having cell openings, and comprising a rib region defining the cell openings;
a membrane comprising cell regions respectively located above the cell openings and a grid region on the rib region; and
first ruler patterns overlapping the rib region in a thickness direction of the mask frame, the first ruler patterns being located at the grid region and spaced from each other by a first interval along a first direction traversing the membrane.
